(19) United States
(12) Patent Application Publication
(10) Pub. No.: US 2013/0343124 A1
(43) Pub. Date: Dec. 26, 2013

(54) SEMICONDUCTOR MEMORY DEVICE AND OPERATION METHOD FOR SAME

(71) Applicant: KABUSHIKI KAISHA TOSHIBA, Tokyo (JP)

(72) Inventors: Sibo Ma, Kanagawa-ken (JP); Masahiro Yoshihara, Kanagawa-ken (JP)

(73) Assignee: Kabushiki Kaisha Toshiba, Tokyo (JP)

(21) Appl. No.: 13/845,509

(22) Filed: Mar. 18, 2013

(30) Foreign Application Priority Data
Jun. 21, 2012 (JP) 2012-139737

(51) Int. Cl. G11C 16/34

(52) U.S. Cl. CPC G11C 16/3427
USPC 365/185.02

(57) ABSTRACT

According to one embodiment, a control circuit is configured to perform a first read operation and a second read operation. The control circuit is configured to perform the plurality of first sense operations when applying a first reading voltage to the word line in the first read operation. The control circuit is configured to perform a second sense operation when applying a second reading voltage to the word line in the second read operation. The control circuit is configured to select one of informations read out by the plurality of sense operations based on data stored in adjacent memory cells.

### CROSS-REFERENCE TO RELATED APPLICATIONS

This application is based upon and claims the benefit of priority from the prior Japanese Patent Application No.2012-139737, filed on Jun. 21, 2012; the entire contents of which are incorporated herein by reference.

### FIELD

Embodiments described herein relate generally to a semiconductor memory device and an operation method for the same.

### BACKGROUND

In NAND flash memory which is one type of semiconductor memory device, data is programmed by changing the threshold of a memory cell transistor by storing a charge in a charge storage layer. On the other hand, the data that is programmed is read by applying a prescribed potential to the control electrode of the memory cell transistor and determining whether the memory cell transistor is in an ON state or in an OFF state.

However, as the downscaling of NAND flash memory progresses, the distance between the charge storage layers of mutually-adjacent memory cell transistors becomes short; adjacent cell coupling (the Yupin effect) occurs; and the precision when reading the data decreases. On the other hand, a faster read-out operation is necessary in NAND flash memory.

### BRIEF DESCRIPTION OF THE DRAWINGS

FIG. 1 is a circuit diagram showing a semiconductor memory device according to a first embodiment;

FIG. 2 is a circuit diagram showing a sense amplifier of the semiconductor memory device according to the first embodiment;

FIGS. 3A and 3B are cross-sectional views showing memory cell transistors of the semiconductor memory device according to the first embodiment;

FIGS. 4A to 4D are graphs showing changes of the threshold distributions of the memory cell transistors;

FIG. 5 is a graph showing the programming order of pages inside each of the blocks;

FIG. 6 is a graph showing the change of the programming potential in the U page program;

FIGS. 7A to 7E are graphs showing the change of the threshold distributions of the memory cell transistors in the U page program;

FIG. 8 shows the degree of the effect of the combination of the value of the object cell and the value of the adjacent cell on the fluctuation of the threshold of the object cell;

FIGS. 9A and 9B are circuit diagrams showing operations of the sense amplifier;

FIG. 10 is a graph showing the potential change during the sensing;

FIG. 11A is a graph showing the fluctuation of the threshold distribution of the object cell caused by the adjacent cells; and

FIG. 11B is a graph showing the I-V characteristics of the memory cell transistors;

FIGS. 12A and 12B are timing charts showing the operation of the L page read of the first embodiment;

FIGS. 13A and 13B are timing charts showing the operation of the U page read of the first embodiment;

FIGS. 14A and 14B are timing charts showing the operation of the U page read of a first comparative example;

FIGS. 15A and 15B are timing charts showing the operation of the L page read of a second comparative example;

FIGS. 16A and 16B are timing charts showing the operation of a U page read of the second comparative example;

FIGS. 17A to 17C are timing charts showing the operation of the U page read of a second embodiment;

FIGS. 18A to 18C are timing charts showing the operation of the U page read of a third embodiment;

FIGS. 19A and 19B are timing charts showing the operation of the U page read of a fourth embodiment; and

FIGS. 20A to 20C are timing charts showing the operation of the U page read of a sixth embodiment.

### DETAILED DESCRIPTION

In general, according to one embodiment, a semiconductor memory device includes a plurality of memory cells, a plurality of sense amplifiers, a plurality of bit lines, a word line and a control circuit. The plurality of bit lines are configured to connect the sense amplifiers to the memory cells. The word line is commonly connected the memory cells. The control circuit is configured to perform a first read operation and a second read operation. The control circuit is configured to perform the plurality of first sense operations when applying a first reading voltage to the word line in the first read operation. The control circuit is configured to perform a second sense operation when applying a second reading voltage to the word line in the second read operation. The control circuit is configured to select one of informations read out by the plurality of sense operations based on data stored in adjacent memory cells.

In general, according to one embodiment, a semiconductor memory device includes a semiconductor substrate, a plurality of word lines, a plurality of bit lines, a source line, charge storage layers, sense amplifiers and a control circuit. The semiconductor substrate includes a plurality of active areas to extend in a first direction. The plurality of word lines are provided on the semiconductor substrate. The word lines extend in a second direction. The plurality of bit lines are connected respectively to the active areas. The source line is connected to the plurality of active areas. The charge storage layers are disposed between each of the active areas and each of the word lines. The sense amplifiers are connected to the bit lines. Each of the sense amplifiers includes a plurality of data latches. Memory cell transistors are formed at intersections between each of the active areas and each of the word lines. The memory cell transistors are configured to be programmed with data having values of multiple levels. The control circuit is configured to use a plurality of reading conditions to discriminate the data stored in a plurality of the memory cell transistors of one of the word lines while applying a first reading potential to the one of the word lines and respectively store the results discriminated using the reading conditions in the data latches. The control circuit is configured to discriminate, while applying a second reading potential to the one of the word lines, the data stored in the memory cell transistors of the one of the word lines. The control circuit is configured to employ one selected from the results stored in the plurality of data latches for one of the memory cell transistors based on the discrimination result when the second reading potential is applied to the memory cell transistor disposed adjacently to the one of the memory cell transistors.

In general, according to one embodiment, an operation method for a semiconductor memory device, includes performing a first read operation to perform a plurality of first sense operations for a plurality of memory cells while applying a first reading voltage to a word line connected to the memory cells. The method includes performing a second read operation to perform a second sense operation for the plurality of memory cells while applying a second reading voltage to the word line. And, the method includes selecting one of data read out by the plurality of the first sense operations for one of the memory cells based on data stored in adjacent memory cells of the one of the memory cells read out by the second sense operation.

Embodiments of the invention will now be described with reference to the drawings.

First, a first embodiment will be described.

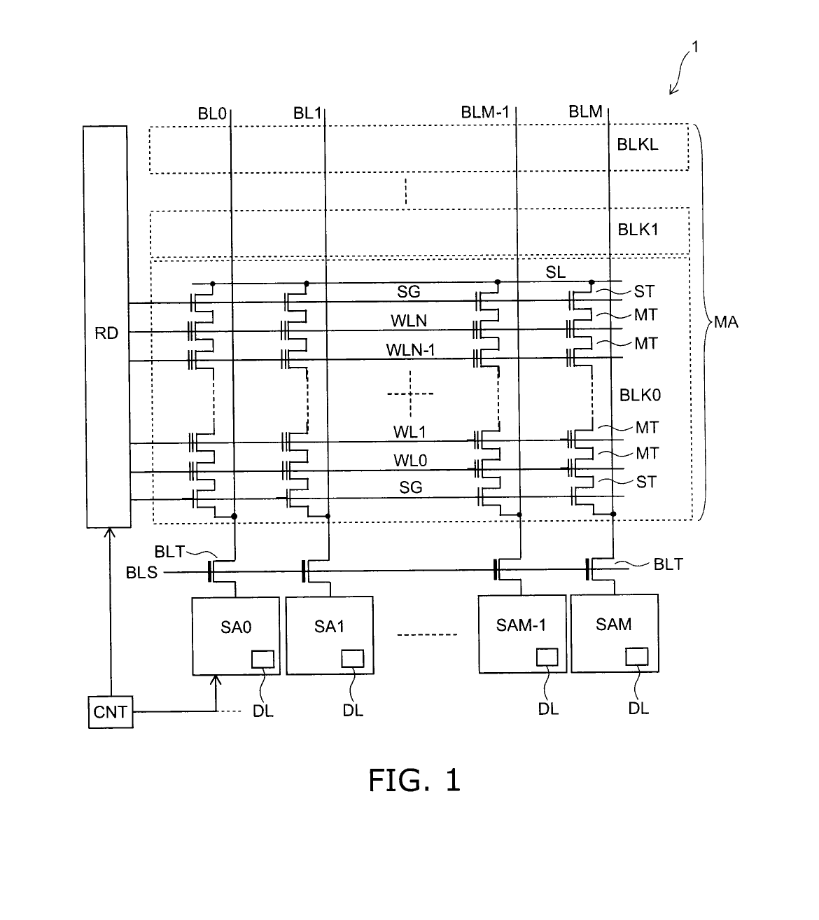

FIG. 1 is a circuit diagram showing a semiconductor memory device according to the embodiment.

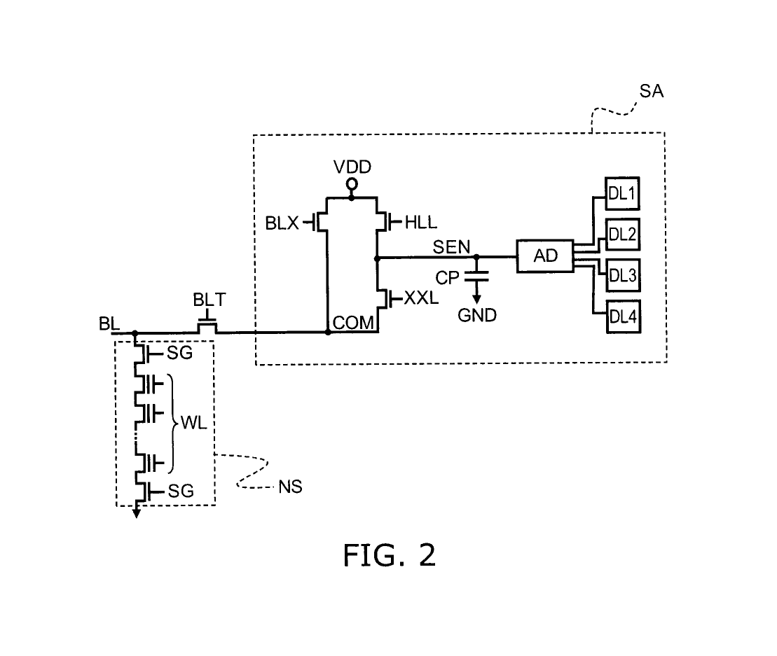

FIG. 2 is a circuit diagram showing a sense amplifier of the semiconductor memory device according to the embodiment.

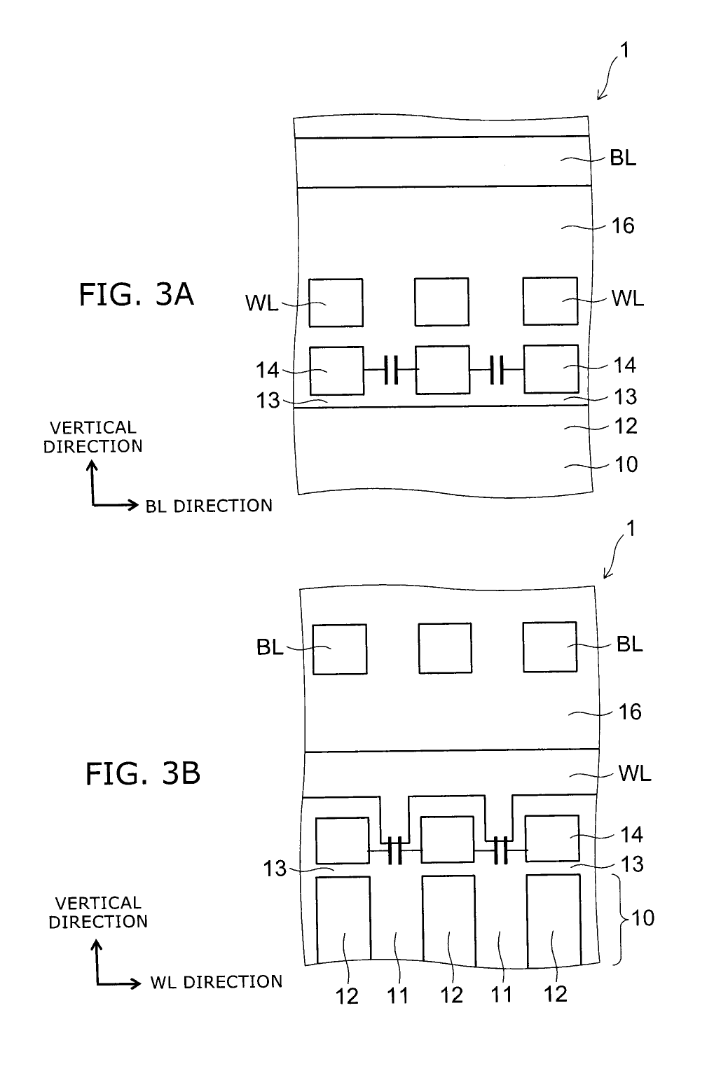

FIGS. 3A and 3B are cross-sectional views showing memory cell transistors of the semiconductor memory device according to the embodiment.

The semiconductor memory device according to the embodiment is NAND flash memory.

First, the configuration of the semiconductor memory device 1 will be described from the circuit aspect.

As shown in FIG. 1, the semiconductor memory device 1 according to the embodiment includes a memory cell array MA that stores data, a row decoder RD, multiple sense amplifiers SAO to SAM (hereinbelow, also generally referred to as the sense amplifier SA, where M is an integer not less than 1), and a control circuit CNT that performs the programming, the reading, the erasing, etc., of the data to the memory cell array MA via the row decoder RD and the sense amplifiers SA. Multiple blocks BLK0 to BLKL (hereinbelow, also generally referred to as the block BLK, where L is an integer not less than 0) are provided in the memory cell array MA.

The semiconductor memory device 1 further includes multiple bit lines BL0 to BLM (hereinbelow, also generally referred to as the bit line BL), multiple word lines WL0 to WLN (hereinbelow, also generally referred to as the word line WL, where N is an integer not less than 1), a source line SL, selection gate lines SG, and a bit line control line BLS. One selection transistor ST, N memory cell transistors MT, and one selection transistor ST are connected in this order in series between the source line SL and the bit line BL to form a NAND string NS. The gate electrodes of the selection transistors ST are connected to the selection gate lines SG; and the control gate electrodes of the memory cell transistors MT are connected to the word lines WL. M NAND strings NS are connected to one source line SL to form one block BLK. The M memory cell transistors MT that share one word line WL are included in one page.

The word lines WL and the selection gate lines SG are connected to the row decoder RD; and the bit lines BL are connected respectively to the sense amplifiers SA. Bit line control transistors BLT are connected between the sense amplifiers SA and the bit lines BL; and the gate electrodes of the bit line control transistors BLT are connected to the bit line control line BLS. The sense amplifiers SA are circuits that apply potentials to the bit lines BL and read the data programmed to the memory cell transistors MT by determining whether the memory cell transistors MT are in the ON state or the OFF state.

As shown in FIG. 2, the sense amplifier SA includes a transistor HLL, a transistor XXL, and a transistor BLX. One end of the transistor HLL is connected to a power supply potential VDD; and one other end of the transistor HLL is connected to one end of the transistor XXL. One end of the transistor BLX also is connected to the power supply potential VDD. One other end of the transistor XXL and one other end of the transistor BLX are connected to a common node COM; and the node COM is connected to one end of the bit line control transistor BLT described above. The connection point between the transistor HLL and the transistor XXL is a node SEN; and a capacitor CP is connected between the node SEN and a ground potential GND. The input of an analog/digital converter AD also is connected to the node SEN; and the outputs of the analog/digital converter AD are connected respectively to data latches DL1 to DL4 (hereinbelow, also generally referred to as the data latch DL). The sense amplifier SA may include components other than those recited above, e.g., data latches other than the data latches DL1 to DL4.

The configuration of the memory cell array MA will now be described from the device aspect.

As shown in FIGS. 3A and 3B, the semiconductor memory device 1 includes a silicon substrate 10, STIs (shallow trench isolation) 11, gate insulating films 13, charge storage layers 14, the word lines WL, the selection gate lines SG, the source line SL, the bit lines BL, and an inter-layer insulating film 16.

The multiple STIs 11 are formed in the upper layer portion of the silicon substrate 10 to extend in one direction (hereinbelow, called the BL direction); and the portions of the upper layer portion of the silicon substrate 10 between the STIs 11 are active areas 12. The gate insulating films 13 are disposed on the active areas 12; and the charge storage layers 14 are disposed on the gate insulating films 13. The charge storage layers 14 are arranged intermittently along the BL direction in the regions directly above the active areas 12. Accordingly, the charge storage layers 14 are arranged in a matrix configuration along both the BL direction and a direction (hereinbelow, called the WL direction) orthogonal to the BL direction in the regions directly above the multiple active areas 12.

The word lines WL described above are disposed on the charge storage layers 14 to extend in the WL direction. The selection gate lines SG are disposed on two sides of a set made of N word lines WL to extend in the WL direction. A bit line contact (not shown) extending in a direction (hereinbelow, called the vertical direction) orthogonal to the BL direction and the WL direction is provided on one side of the group including the set made of the N word lines WL and the pair of selection gate lines SG disposed on the two sides of the set as viewed from the group; and the lower end of the bit line contact is connected to the active area 12. On the other hand, the source line SL extending in the WL direction is disposed on the other side as viewed from the group described above; and the lower end of the source line SL is connected to the active area 12. The bit line BL described above is disposed in the region directly above each of the active areas 12 above the word lines WL, the selection gate lines SG, and the source line SL. The bit line BL extends in the BL direction and is connected to the upper end of the bit line contact. The inter-layer insulating film 16 is positioned on the silicon substrate 10 to cover the charge storage layers 14, the word lines WL, the selection gate lines SG, the source line SL, and the bit line BL.

Thereby, in each of the blocks, the memory cell transistor MT including one charge storage layer 14 is formed at each intersection between each of the active areas 12 and each of the word lines WL. Accordingly, the multiple memory cell transistors MT are arranged in a matrix configuration along the BL direction and the WL direction in the memory cell array MA of the semiconductor memory device 1. Also, the selection transistor ST is formed at each intersection between each of the active areas 12 and each of the selection gate lines SG. The memory cell transistors MT and the selection transistors ST are, for example, n-channel transistors. Operations of the semiconductor memory device according to the embodiment will now be described.

All of the operations described below are performed by the control circuit CNT.

First, a programming operation of data will be described.

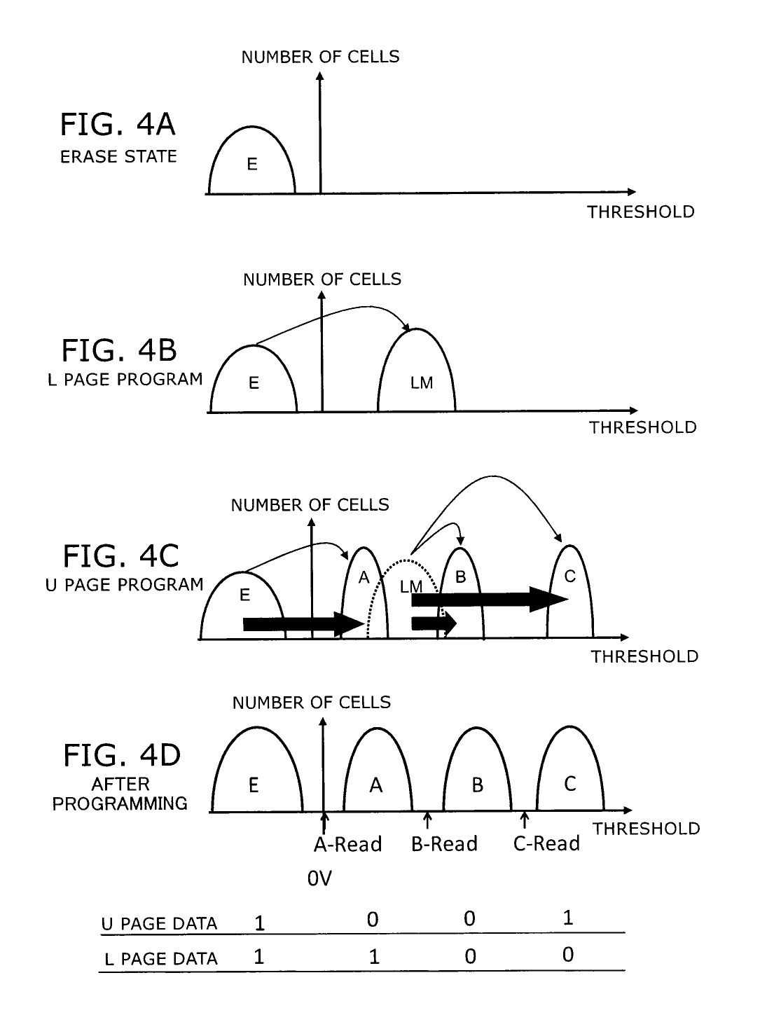

FIGS. 4A to 4D are graphs showing changes of the threshold distributions of the memory cell transistors, where the horizontal axis is the thresholds of the memory cell transistors, and the vertical axis is the number of memory cell transistors (the number of cells). FIG. 4A shows an erase state; FIG. 4B shows a state after an L page program; FIG. 4C shows a state after a U page program; and FIG. 4D shows the relationship between the threshold distributions and the values of the memory cell transistors after the U page program.

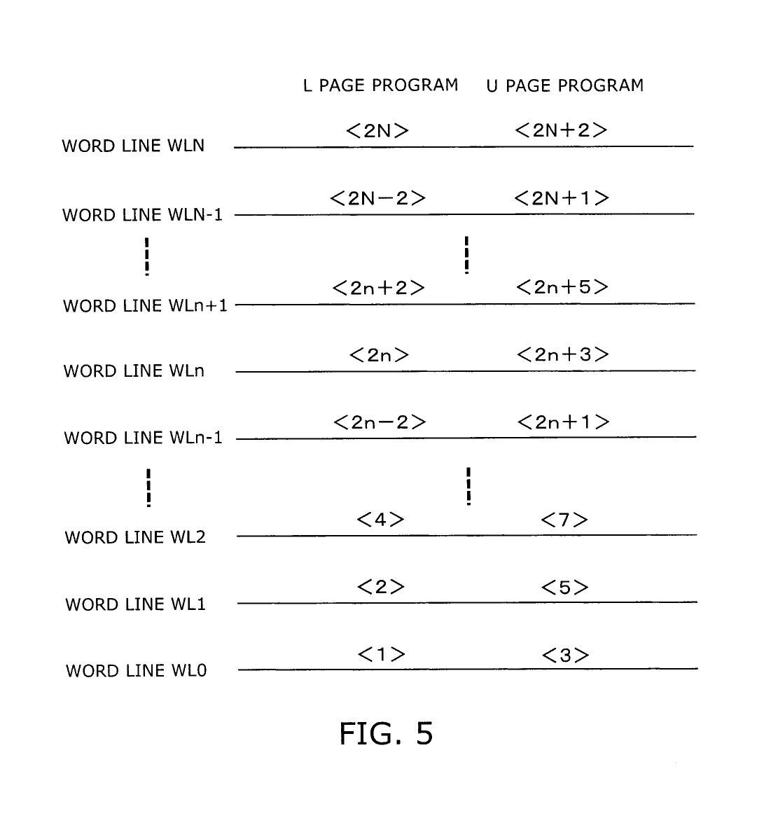

FIG. 5 is a graph showing the programming order of pages inside each of the blocks.

As shown in FIG. 1, FIG. 2, and FIGS. 3A and 3B, when programming the data to the memory cell transistors MT (hereinbelow, also referred to as simply the cells), a positive programming potential is applied to one of the word lines WL; and a pass potential that causes the cells to be in the ON state is applied to the other word lines WL. Then, according to the data input from the outside, for example, the ground potential GND is applied to the bit lines BL connected to the cells to which the values are to be programmed, i.e., the cells for which the thresholds are to be increased, to cause the potentials of the active areas 12 to be the ground potential. Thereby, electrons are injected into the charge storage layers 14 from the active areas 12; and the threshold distributions of the cells shift toward the positive side. On the other hand, for the cells to which values are not programmed, i.e., the cells for which the thresholds are not increased, the active areas 12 are caused to be in the floating state after applying the power supply potential VDD to the bit lines BL. Thereby, the potentials of the active areas 12 increase due to coupling with the word lines WL; and electrons are not injected into the charge storage layers 14 even for the cells for which the programming potential is applied to the word lines WL. This is similar for the cells for which the programming of the values has ended; and further programming is prohibited.

The case where quaternary data is programmed to an n-channel memory cell transistor MT will now be described.

In the embodiment as shown in FIGS. 4A to 4D, the programming of the data is divided into two stages. The values of the data are taken as “E,” “A,” “B,” and “C” from the order of the lowest thresholds of the memory cell transistors MT. For example, the threshold of value “E” is negative; and the thresholds of values “A,” “B,” and “C” are positive.

As shown in FIG. 4A, all of the cells to be programmed with data are caused to be in the erase state in which the data is erased. The value is “E” in the erase state.

From this state, as shown in FIG. 4B, the electrons are injected into the charge storage layers 14 for a portion of the multiple memory cell transistors MT that share one word line WL, i.e., the multiple cells belonging to one page, by selectively applying a potential to the multiple bit lines BL. Thereby, the thresholds of the cells increase; and the threshold distribution shifts toward the positive side. The state after the threshold distribution has shifted is called medium value “LM” for convenience. In the specification, the first programming is called the L page program (Lower page program). After the L page program, the threshold distributions of the cells are divided into value “E” and medium value “LM”.

Then, as shown in FIG. 4C, for a portion of the cells of value “E,” the value is caused to be “A” by injecting a charge into the charge storage layers 14. Also, the charge is injected into a portion of the cells of medium value “LM” to cause the value to be “B.” Further, the charge is injected into the remaining cells of medium value “LM” to cause the value to be “C.” In the specification, the second programming is called the U page program (Upper page program). After the U page program, the threshold distributions are divided into the four levels of values “E,” “A,” “B,” and “C.” In the U page program, the injection amount of the charge when maintaining value “E” is substantially zero; and the injection amount of the charge when changing the value from “LM” to “B” is relatively small. Conversely, the injection amount of the charge when changing the value from “E” to “A” and when changing the value from “LM” to “C” is relatively large.

As shown in FIG. 4D, each of the quaternary data can be handled as two pages of binary data. For example, for value “E” and value “A,” the L page data is set to be “1;” and for value “B” and value “C,” the L page data is set to be “0.” For value “E” and value “C,” the U page data is set to be “1;” and for value “A” and value “B,” the U page data is set to be “0.”

Although such an L page program and such a U page program are performed, for example, for each page from the source line SL side toward the bit line BL side, the L page program and the U page program are almost never executed continuously for the same page. This is because, as shown in FIG. 3A, adjacent cell coupling between cells that are adjacent to each other in the BL direction occurs due to capacitive coupling between the charge storage layers 14 that are adjacent to each other in the BL direction; and the threshold distributions of the cells that are previously programmed fluctuate due to effects of the programming operation of the adjacent cells that are subsequently executed. Specifically, when the charge is injected into the one cell, capacitive coupling causes the potential of the charge storage layer 14 of a cell adjacent to the one cell to decrease and the threshold of the one cell to increase.

Accordingly, if value “E,” “A,” “B,” or “C” is programmed to the cells belonging to one page by performing the L page program and the U page program to the one page and subsequently performing the L page program and the U page program to an adjacent page, the threshold distributions of the cells that were previously programmed fluctuate greatly by being undesirably affected by both the L page program and the U page program of the adjacent cells. The fluctuation amount of the threshold caused by such adjacent cell coupling is not uniform between the cells because the fluctuation amount depends on the data pattern of the surrounding cells, the threshold fluctuation amount of the adjacent cells, the coupling ratio with the surrounding cells, etc. Accordingly, the threshold distributions of the cells undesirably spread each time the cells are affected by the programming of the adjacent cells. In the case where the threshold distributions of the cells spread, the width of the potential between the threshold distributions becomes narrow. As a result, the determination of the values becomes difficult; and the reliability of the read-out operation undesirably decreases.

Therefore, in the embodiment as shown in FIG. 5, <1> the L page program of the word line WL0 is performed; subsequently, <2> the L page program of the word line WL1 is performed; and subsequently, <3> the U page program of the word line WL0 is performed. When generalized using n which is an integer from 2 to (N−1), <2n> the L page program of the word line WLn is performed; subsequently, <2n+1> the U page program of the word line WL (n−1) which is one previous is performed and <2n+2> the L page program of the word line WL (n+1) which is one subsequent is performed; and subsequently, <2n+3> the U page program of the word line WLn is performed. In other words, between the L page program and the U page program of one page, the U page program of the page one previous and the L page program of the page one subsequent are completed. Thus, the effects on one page due to the adjacent cells after performing the U page program to set the threshold distributions having values “A,” “B,” and “C” are only from the U page program of the page one subsequent; and the fluctuation of the threshold distributions can be suppressed.

The adjacent cell coupling from adjacent cells belonging to the same page will now be described.

As shown in FIG. 3B, similarly to the charge storage layers 14 that are adjacent to each other in the BL direction, the charge storage layers 14 that are adjacent to each other in the WL direction also have capacitive coupling. Therefore, adjacent cell coupling occurs also between the cells that are adjacent to each other in the WL direction. As described above, the data is programmed to the cells belonging to the same page at the same timing. However, the timing when the programming ends is different according to the value to be programmed. Therefore, there are cases where the threshold of a cell for which the programming of the value has ended fluctuates due to the effect of an adjacent cell that continues to be programmed thereafter. This phenomenon will now be described.

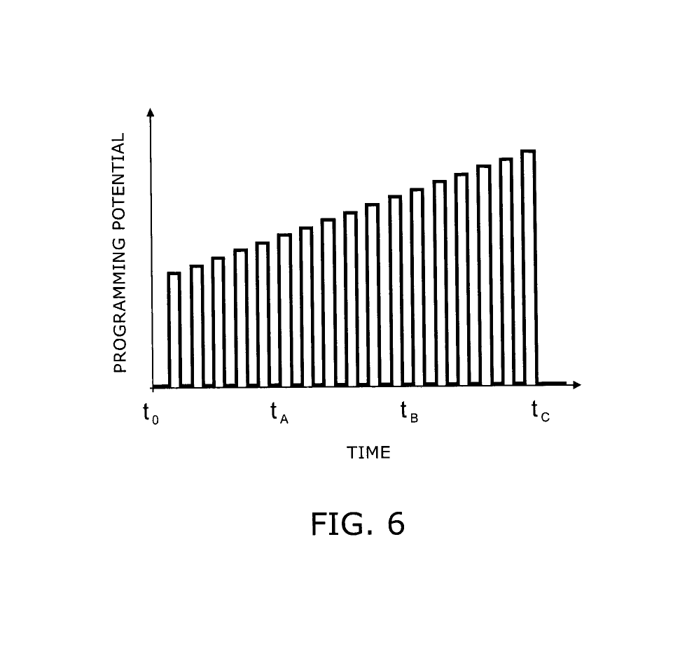

FIG. 6 is a graph showing the change of the programming potential in the U page program, where the horizontal axis is the time, and the vertical axis is the programming potential.

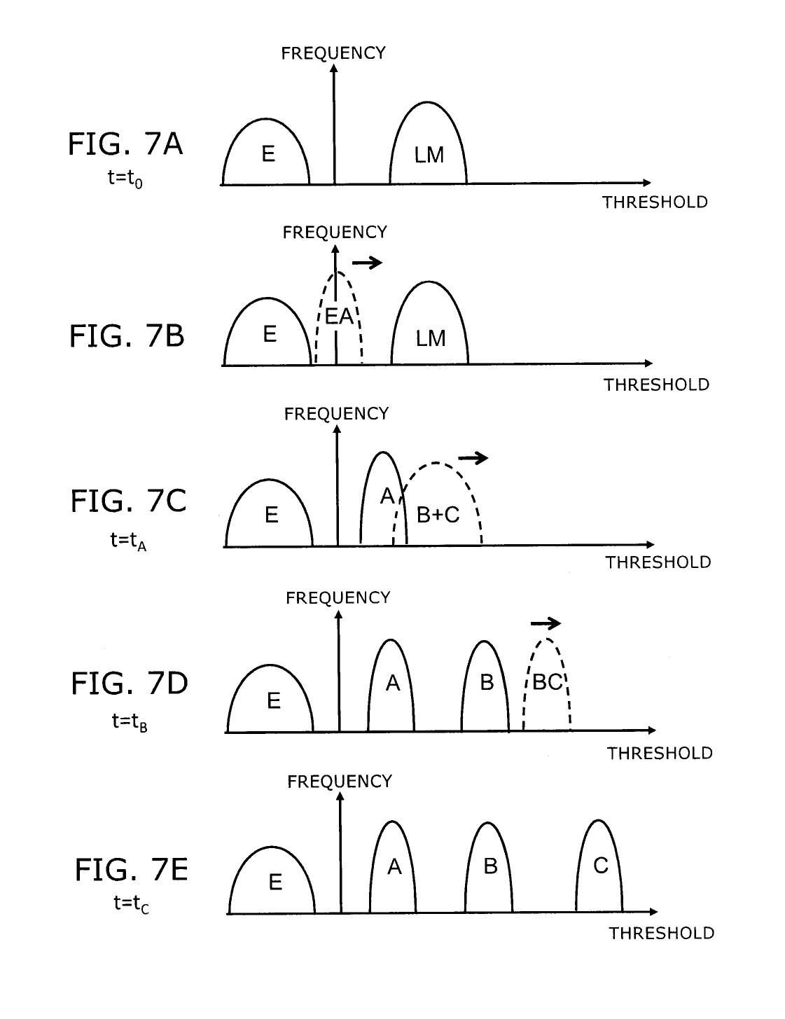

FIGS. 7A to 7E are graphs showing the change of the threshold distributions of the memory cell transistors in the U page program, where the horizontal axis is the thresholds of the memory cell transistors, and the vertical axis is the frequency. In the programming operation as shown in FIG. 6, a programming potential having a pulse form is applied intermittently to the word line WL while gradually increasing the potential. Thereby, the charge is injected into the charge storage layers 14; and the thresholds of the memory cell transistors gradually increase. As shown in FIG. 7A, the threshold distribution at a point in time (time t₀) after the L page program ends and prior to the U page program is divided into the distribution of value “E” and the distribution of medium value “LM.” The threshold distribution of value “E” is already established at this stage. When the programming potential is applied from this state as shown in FIG. 6, the thresholds of the memory cell transistors to be programmed with value “A” start to move in the positive direction from the threshold distribution of value “E” as shown in FIG. 7B. In FIG. 7B, this threshold distribution is illustrated as “EA” for convenience. Then, at time t₀ as shown in FIG. 7C, the thresholds of the memory cell transistors to be programmed with value “A” are established to exceed the desired threshold to have the threshold distribution of value “A.” At this stage, the threshold distribution of medium value “LM” also spreads. As the application of the programming potential continues, the thresholds of the memory cell transistors to be programmed with value “B” are established to exceed the desired threshold to have the threshold distribution of value “B” at time t_{B} as shown in FIG. 7D. At this stage, the threshold distribution that will become value “C” is moving in the positive direction. In FIG. 7D, this threshold distribution is illustrated as “BC” for convenience. Then, at time t_{c} as shown in FIG. 7E, the thresholds of the memory cell transistors to be programmed with value “C” are established to exceed the desired threshold to have the threshold distribution of value

“C.” Thereby, the U page program ends.

Thus, the thresholds of the cells are established in order from the lowest value. Therefore, the value programmed to one cell (hereinbelow, called the object cell) undesirably fluctuates due to the effect of the programming to a cell (hereinbelow, called the adjacent cell) disposed adjacently to the object cell in the WL direction in the case where the value programmed to the adjacent cell is higher than the value programmed to the object cell. Also, the fluctuation amount of the threshold of the object cell is different according to the combination of the value of the object cell and the value of the adjacent cell. Therefore, the threshold distribution of the object cell fluctuates to spread in the direction of higher thresholds.

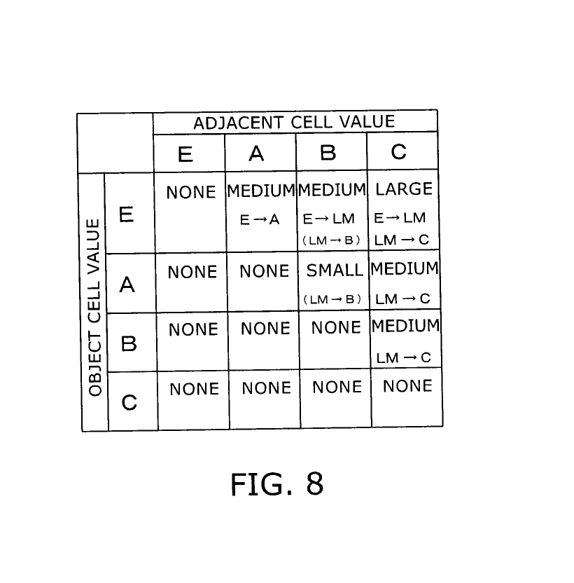

FIG. 8 shows the degree of the effect of the combination of the value of the object cell and the value of the adjacent cell on the fluctuation of the threshold of the object cell.

As described above, the object cell and the adjacent cell share the same word line WL and belong to the same page.

As shown in FIG. 8, in the case where the value of the object cell is “E” and the value of the adjacent cell is “E,” there is substantially no adjacent cell coupling of the object cell from the adjacent cell because substantially no charge is injected into the adjacent cell. Hereinbelow, the case where there is substantially no adjacent cell coupling and the case where absolutely no adjacent cell coupling are illustrated by “none” in FIG. 8.

In the case where the value of the object cell is “E” and the value of the adjacent cell is “A,” the object cell is affected when the value of the adjacent cell changes from “E” to “A.” In other words, the object cell is affected once by the change from value “E” to value “A” for which the injection amount of the charge is relatively large. Thus, hereinbelow, the case of being subjected to the change for which the injection amount of the charge is relatively large is illustrated as a medium degree of adjacent cell coupling by “medium” in FIG. 8.

In the case where the value of the object cell is “E” and the value of the adjacent cell is “B,” the object cell is affected when the value of the adjacent cell changes from “E” to “LM” in the L page program and when the value of the adjacent cell changes from “LM” to “B” in the U page program. In other words, the object cell is affected once by the change from value “E” to medium value “LM” for which the injection amount of the charge is relatively large and is affected once by the change from medium value “LM” to value “B” for which the injection amount of the charge is relatively small. In such a case as well, these are illustrated by “medium” in FIG. 8 because the change for which the injection amount of the charge is relatively large is only once.

In the case where the value of the object cell is “E” and the value of the adjacent cell is “C,” the object cell is affected when the value of the adjacent cell changes from “E” to “LM” in the L page program and is affected when the value of the adjacent cell changes from “LM” to “C” in the U page program. In such a case, this is illustrated by “large” in FIG. 8 because there are two changes for which the injection amount of the charge is relatively large and the adjacent cell coupling is large.

In the case where the value of the object cell is “A” and the value of the adjacent cell is “E” or “A,” there is substantially no adjacent cell coupling because the adjacent cell is not programmed after the programming of the object cell ends. Accordingly, this is illustrated by “none” in FIG. 8.

In the case where the value of the object cell is “A” and the value of the adjacent cell is “B,” the object cell is affected when the value of the adjacent cell changes from “LM” to “B.” In other words, the object cell is affected once by the change from medium value “LM” to value “B” for which the injection amount of the charge is relatively small. Thus, the case of being subjected to only the change for which the injection amount of the charge is relatively small is illustrated as a small degree of adjacent cell coupling by “small” in FIG. 8. In the case where the value of the object cell is “A” and the value of the adjacent cell is “C,” the object cell is affected when the value of the adjacent cell changes from “LM” to “C.” In other words, the object cell is affected once by the change from medium value “LM” to “C” for which the injection amount of the charge is relatively large. Accordingly, this is illustrated by “medium” in FIG. 8.

In the case where the value of the object cell is “B” and the value of the adjacent cell is “E,” “A,” or “B,” there is substantially no adjacent cell coupling because the adjacent cell is not programmed after the programming of the object cell ends. Accordingly, this is illustrated by “none” in FIG. 8.

In the case where the value of the object cell is “B” and the value of the adjacent cell is “C,” the object cell is affected when the value of the adjacent cell changes from “B” to “C.” In other words, this is illustrated by “medium” in FIG. 8 because the object cell is affected once by the change from value “B” to “C” for which the injection amount of the charge is relatively large.

In the case where the value of the object cell is “C” and the value of the adjacent cell is “E,” “A,” “B,” or “C,” there is substantially no adjacent cell coupling because the adjacent cell is not programmed after the programming of the object cell ends. Accordingly, this is illustrated by “none” in FIG. 8.

Thus, the case where the adjacent cell coupling between the cells that are adjacent to each other in the WL direction becomes the largest is the case where the value of the object cell is “E” and the value of the adjacent cell is “C”. Accordingly, in the read-out operation, the case of being particularly affected by the fluctuation of the threshold distributions is the case where the value of the adjacent cell is “C” and it is discriminated whether or not the value of the object cell is “E.” Thus, in the case where there is a possibility that the value of the object cell is “E,” the degree of the adjacent cell coupling can be differentiated by whether the value of the adjacent cell is “C” or a value other than “C.”

The effect of the adjacent cell coupling on the object cell can be divided into three cases according to the combination of the values of the two adjacent cells positioned on two adjacent sides. In other words, the effect on the object cell is largest in the case where both of the values of the two adjacent cells positioned on the two adjacent sides are “C;” the effect on the object cell is next largest in the case where the value of one of the two adjacent cells is “C” and the value of the other of the two adjacent cells is a value other than “C;” and the effect on the object cell is the smallest in the case where both of the values of the two adjacent cells are values other than “C.”

A read-out operation of the data will now be described.

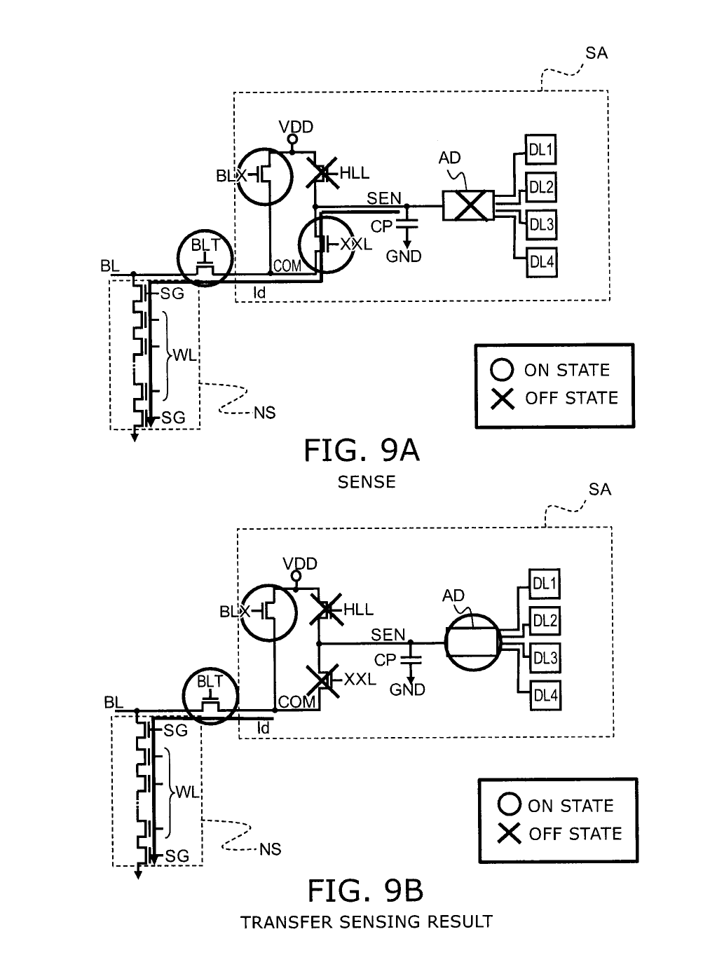

FIGS. 9A and 9B are circuit diagrams showing operations of the sense amplifier. FIG. 9A shows the sensing operation; and FIG. 9B shows an operation that transfers the sensing result.

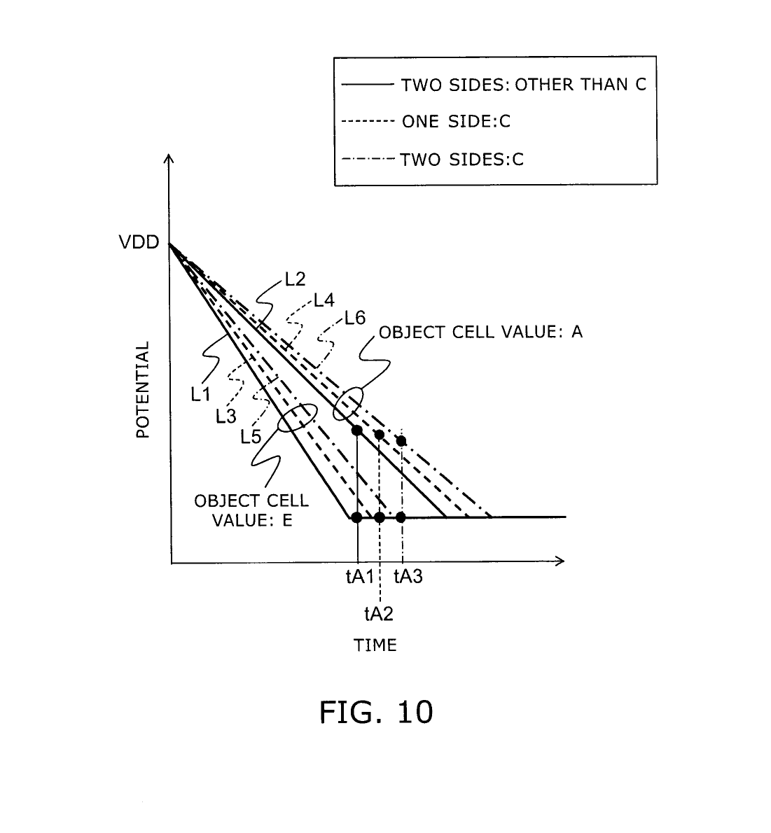

FIG. 10 is a graph showing the potential change during the sensing, where the horizontal axis is the time, and the vertical axis is the potential of the positive side of the capacitor.

When reading the data programmed to a cell as described below, the threshold of the cell is compared to a reference value and a discrimination of whether the threshold is high or low is multiply performed. In each of the discriminations, the prescribed reading potential is applied to the word line WL; and it is determined whether the cell is in the OFF state or the ON state.

First, operations common to the discrimination of the threshold will be described.

When reading the data programmed to the cell as shown in FIG. 2, the interconnect of the node SEN is charged and the capacitor CP is caused to store the charge by switching the transistors BLX, BLT, and XXL to the OFF state and switching the transistor HLL to the ON state. Thereby, the potential of the node SEN is substantially the power supply potential VDD.

Then, the prescribed reading potential is applied to the word line WL. As shown in FIG. 4D, for example, in the case where it is discriminated whether the value of the cell is “E” or whether the value of the cell is other than “E,” the reading potential is a potential A-Read that is higher than the upper limit of the threshold distribution of the cells programmed with value “E” and lower than the lower limit of the threshold distribution of the cells programmed with value “A.” A pass potential that is high enough that the memory cell transistors MT are switched to the ON state regardless of the values of the memory cell transistors MT is applied to the remaining word lines WL.

As shown in FIG. 9A in this state, the transistor HLL of the sense amplifier SA is switched to the OFF state; and the transistors XXL, BLX, and BLT are switched to the ON state. Thereby, the charge stored in the capacitor CP flows in the source line SL by way of the transistor XXL, the transistor BLT, the bit line BL, and the active area 12 as a cell current Id. By the cell current Id flowing and the charge stored in the capacitor CP being discharged, the potential of the node SEN decreases from the power supply potential VDD and decreases to the same potential as the node COM, i.e., the potential that is between the power supply potential VDD and the ground potential GND due to the resistance division between the resistance of the transistor BLX and the total resistance of the transistor BLT and the NAND string NS.

At this time, as shown in FIG. 10, in the case where the reading potential is, for example, the potential A-Read, if value “E” is programmed to the cell to be read, the cell current Id becomes relatively large because the cell is switched to the ON state. Thereby, the constant amount of the charge stored in the capacitor CP is discharged in a relatively short period of time; and the decrease rate of the potential of the node SEN becomes large. On the other hand, if a value other than value “E” is programmed to the cell, the current Id becomes relatively small because the cell is switched to the OFF state. Thereby, the constant amount of the charge stored in the capacitor CP is discharged in a relatively long period of time; and the decrease rate of the potential of the node SEN becomes low. A change amount ΔV of the potential is ΔV=I×t/C, where the change amount of the potential is AV, the magnitude of the cell current is I, the amount of charge discharged from the capacitor CP is C, and the time is t.

Then, at some time as shown in FIG. 9B and FIG. 10, the analog/digital converter AD is activated after electrically isolating the node SEN from the NAND string NS by switching the transistor XXL to the OFF state. Thereby, the potential of the node SEN is input to the analog/digital converter AD. The analog/digital converter AD converts the analog signal that is input into a digital signal and outputs the digital signal. Thereby, the value of the object cell can be discriminated by measuring the potential of the node SEN, i.e., the potential of the positive side of the capacitor CP. In other words, if the potential of the node SEN is lower than a reference value, it can be determined that the object cell is in the ON state and, accordingly, the value of the object cell is “E.” On the other hand, if the potential of the node SEN is higher than the reference value, it can be determined that the object cell is in the OFF state and, accordingly, the value of the object cell is a value other than “E.” The operation described above also is similar for the cases where the reading potential is B-Read and the reading potential is C-Read.

However, as described above, the threshold distribution of the cell fluctuates due to effects of the adjacent cells. The effect is particularly large in the case where the value of the object cell is “E” and the value of the adjacent cell is “C.” The effect of the value of the adjacent cell on the timing of the measurement of the potential of the node SEN in such a case will now be described.

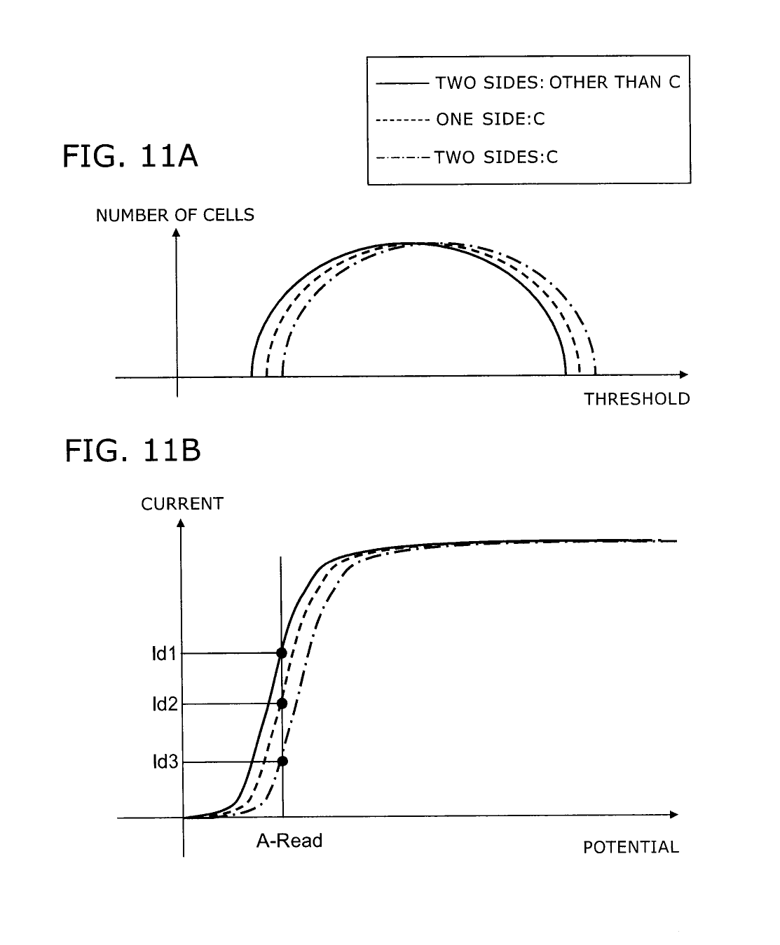

FIG. 11A is a graph showing the fluctuation of the threshold distribution of the object cell caused by the adjacent cells, where the horizontal axis is the threshold, and the vertical axis is the number of memory cell transistors (the number of cells); and FIG. 11B is a graph showing the I-V characteristics of the memory cell transistors, where the horizontal axis is the potential of the control gate, and the vertical axis is the current flowing between the source and drain.

As shown in FIG. 11A, compared to the threshold distribution of the case where both of the values of the adjacent cells on the two sides are values other than “C” (hereinbelow, also referred to as “two sides: other than C”), the threshold distribution of the case where the value of one of the adjacent cells on the two sides is “C” and the value of the other of the adjacent cells on the two sides is a value other than “C” (hereinbelow, also referred to as “one side: C”) is shifted toward the positive side; and the threshold distribution of the case where both of the values of the adjacent cells on the two sides are “C” (hereinbelow, also referred to as “two sides: C”) is shifted further toward the positive side. Therefore, as shown in FIG. 11B, even when applying the same potential A-Read to the word line WL, compared to a cell current Id1 flowing in the case of “two sides: other than C”, a cell current Id2 flowing in the case of “one side: C” is small; and a cell current Id3 flowing in the case of “two sides: C” is even smaller.

As a result, as shown in FIG. 10, compared to the potential change of the node SEN in the case of “two sides: other than C” (the solid lines L1 and L2), the potential change in the case of “one side: C” (the broken lines L3 and L4) is gradual; and the potential change in the case of “two sides: C” (the single dot-dash lines L5 and L6) is more gradual. Accordingly, compared to time tA1 which is suited to the sensing in the case of “two sides: other than C”, time tA2 which is suited to the sensing in the case of “one side: C” is a later time; and time tA3 which is suited to the sensing in the case of “two sides: C” is an even later time.

The sequence of the entire read-out operation will now be described.

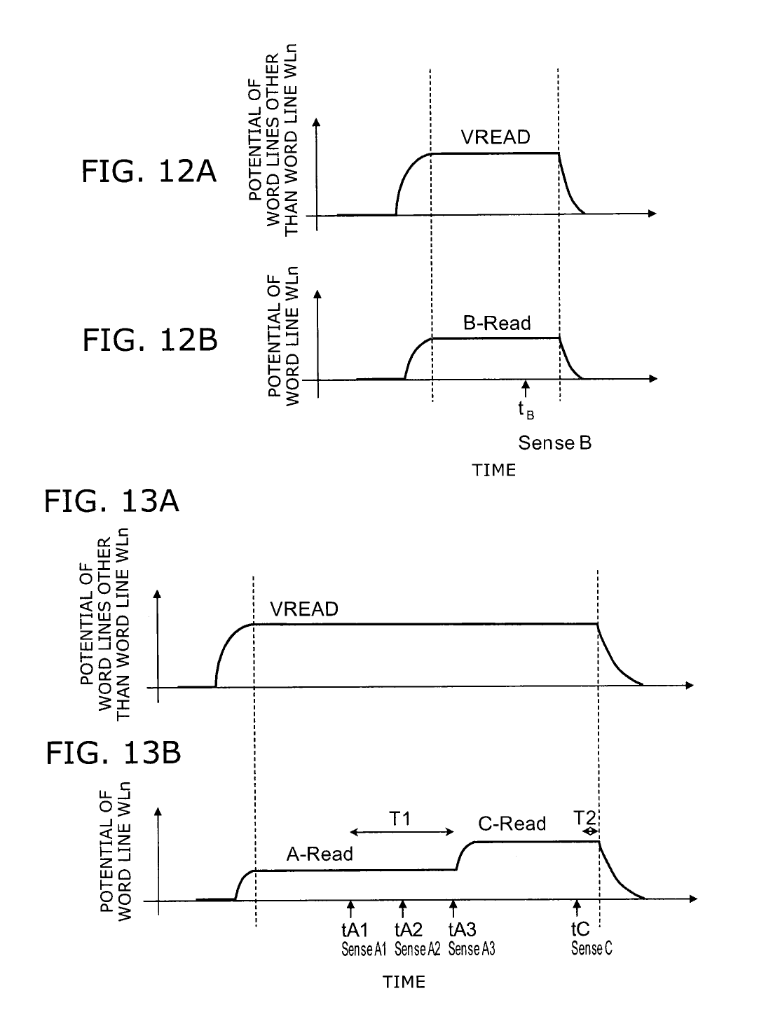

FIGS. 12A and 12B are timing charts showing the operation of the L page read of the embodiment, where the horizontal axis is the time, and the vertical axis is the potentials.

FIGS. 13A and 13B are timing charts showing the operation of the U page read of the embodiment, where the horizontal axis is the time, and the vertical axis is the potentials.

In the embodiment as shown in FIG. 4D, the data that is originally quaternary is read by being divided into the binary L page data and the binary U page data.

In the L page read as shown in FIGS. 12A and 12B, the potential B-Read which is between the threshold distribution of value “A” and the threshold distribution of value “B” is applied as the reading potential to the word line WLn to be read (n being an integer of 1 to N). On the other hand, a pass potential VREAD that causes the memory cell transistors to be switched to the ON state regardless of the values that are stored is applied to the word lines other than the word line WLn. In this state, as described above, the cell current Id is caused to flow in the NAND string from each of the sense amplifiers SA; and at time tB, by the operation described above, the analog/digital converter AD converts the potential of the node SEN to a digital signal and determines the state of the object cell (Sense B). Then, if the object cell is in the ON state, the L page data is caused to be value “1.” On the other hand, if the object cell is in the OFF state, the L page data is caused to be value “0.”

Thus, it is discriminated whether the value of the object cell is a first group (L page data: 1) made of the threshold distribution being the lowest value “E” or the second lowest value “A” or whether the value of the object cell is the second group (L page data: 0) made of the threshold distribution being the third lowest value “B” or the highest value “C.” Hereinbelow, the discrimination of the cell performed by thus applying the reading potential B-Read to the word line WLn also is referred to as B-Read discrimination. Subsequently, the potentials of all of the word lines WL are returned to the ground potential GND.

In the U page read as shown in FIGS. 13A and 13B, first, the potential A-Read which is between the threshold distribution of value “E” and the threshold distribution of value “A” is applied as the reading potential to the word line WLn to be read. On the other hand, the pass potential VREAD is applied to the word lines other than the word line WLn. Then, the cell current Id is caused to flow in the NAND string from each of the sense amplifiers SA; and the analog/digital converter AD converts the potential of the node SEN into a digital signal for each of times tA1, tA2, and tA3. Thereby, it is discriminated whether the value of the object cell is “E” or a value other than “E” (Sense A1, Sense A2, and Sense A3). The discrimination of the cell performed by thus applying the reading potential A-Read to the word line WLn also is referred to as A-Read discrimination. Then, the discrimination results are stored respectively in the data latches DL1, DL2, and DL3.

Thus, in the embodiment, the control circuit CNT discriminates the value of the object cell using a first condition at which the A-Read discrimination is possible in the case of “two sides: other than C” and stores the result of the discrimination in the data latch DL1; the control circuit CNT discriminates the value of the object cell using a second condition at which the A-Read discrimination is possible in the case of “one side: C” and stores the result of the discrimination in the data latch DL2; and the control circuit CNT discriminates the value of the object cell using a third condition at which the A-Read discrimination is possible in the case of “two sides: C” and stores the result of the discrimination in the data latch DL3. Accordingly, the potential of the node SEN is measured three times in the A-Read discrimination.

Then, the potential of the word line WLn is increased to the potential C-Read which is between the threshold distribution of value “B” and the threshold distribution of value “C” while the potential of the word lines other than word line WLn are maintained at the pass potential VREAD. In this state, at time tC, the state of the object cell is determined by performing the read-out operation described above. Thereby, it is discriminated whether the value of the object cell is “C” or a value other than “C” (Sense C). Hereinbelow, the discrimination of the cell performed by thus applying the reading potential C-Read to the word line WLn also is referred to as C-Read discrimination. Then, the result of the C-Read discrimination is stored in the data latch DL4.

At this point in time, it is ascertained whether the values of the cells belonging to the page to be read are “C” or other than “C.” Accordingly, for one object cell, it is ascertained whether or not the values of the two adjacent cells are “C.” Then, as the result of the A-Read discrimination of the object cell (the discrimination of whether the value is “E” or a value other than “E”), the control circuit CNT employs the result stored in the data latch DL1, i.e., the result sensed at time tA1, in the case of “two sides: other than C”; the control circuit CNT employs the result stored in the data latch DL2, i.e., the result sensed at time tA2, in the case of “one side: C”; and the control circuit CNT employs the result stored in the data latch DL3, i.e., the result sensed at time tA3, in the case of “two sides: C”.

Then, the U page data is caused to be value “1” in the case where the object cell is switched to the ON state when the reading potential is the potential A-Read, that is, in the case where the value of the object cell is “E;” and the U page data is caused to be value “1” in the case where the object cell is switched to the OFF state when the reading potential is the potential C-Read, that is, in the case where the value of the object cell is “C.” On the other hand, the U page data is caused to be value “0” in the case of being switched to the OFF state when the reading potential is the potential A-Read and switched to the ON state when the reading potential is the potential C-Read, that is, in the case where the value of the object cell is “A” or “B.” Thereby, the read-out operation ends.

In the case where the cell is in the ON state at all of times tA1, tA2, and tA3, it is established that the value is “E” without needing to evaluate the values of the adjacent cells by performing the C-Read discrimination. Accordingly, the potential of the bit line BL connected to the cell may be reduced to the ground potential GND after time tA3.

Effects of the embodiment will now be described.

In the embodiment, as shown in FIG. 13B, the A-Read discrimination is performed at each of times tA1, tA2, and tA3; and the results are stored in the data latches DL1 to DL3.

Thereby, as shown in FIGS. 11A and 11B, the A-Read discrimination can be performed using the appropriate condition corresponding to the threshold distribution for each of the cases of “two sides: other than C”, “one side: C”, and “two sides: C”; and subsequently, after discriminating whether or not the values of the adjacent cells are “C” by performing the C-Read discrimination, the most appropriate result of the three types of A-Read discrimination results stored in the data latches DL1 to DL3 is employed based on the combination of the values of the adjacent cells. Thereby, the data can be read with high precision even in the case where the fluctuation of the threshold distribution is particularly likely, that is, in the case where the values of the adjacent cells are “C” and the A-Read discrimination is performed on the object cell.

In the embodiment, the discriminations at times tA1, tA2, and tA3 are performed in the state in which the potentials of the word lines WL other than the word line WLn are fixed at the pass potential VREAD and the potential of the word line WLn of the page to be read is fixed at the reading potential A-Read. Therefore, it is unnecessary to change the potentials of the word lines WL between times tA1, tA2, and tA3. As a result, the time to charge the word lines becomes unnecessary; and the read-out operation can be performed in a short period of time.

In the embodiment, the three types of discrimination results are acquired only in the case of being particularly affected by the fluctuation of the threshold distributions, that is, in the case where the value of the adjacent cell is “C” and the A-Read discrimination of the object cell is performed. Thereby, the precision of the read-out operation can be increased efficiently without drastically increasing the read-out time.

In the embodiment, the potential of the word line WLn of the page to be read is firstly set to be the reading potential A-Read and subsequently is set to be the reading potential C-Read. When the potential of the word line WLn is set to be the reading potential A-Read, the cell current flows in only the cells for which the value is “E.” On the other hand, when the potential of the word line WLn is set to be the reading potential C-Read, the cell current flows in the cells for which the value is “E,” “A,” or “B.” Therefore, as described above, the current consumption of the entire device can be suppressed by reducing the potential of the bit line BL to the ground potential GND for the cells for which it is established that the value is “E” at the time of the discrimination at time tA3.

A first comparative example will now be described.

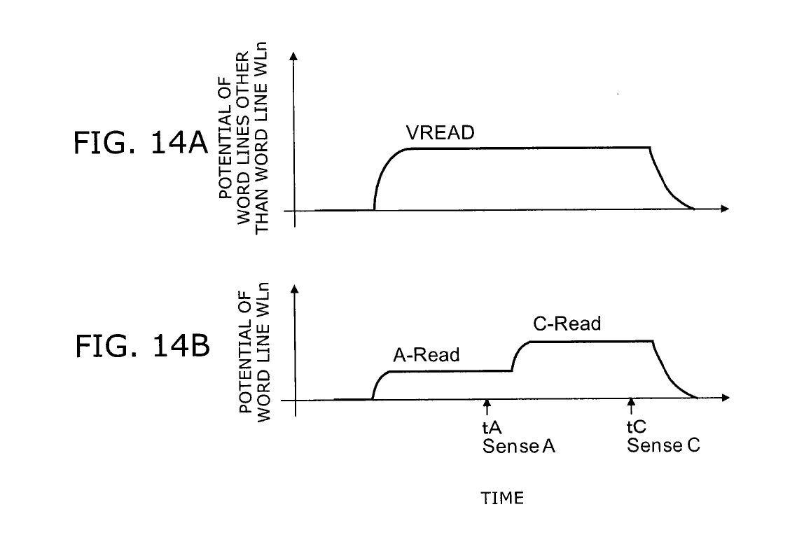

FIGS. 14A and 14B are timing charts showing the operation of the U page read of the comparative example, where the horizontal axis is the time, and the vertical axis is the potentials.

In the U page read of the comparative example as shown in FIGS. 14A and 14B, the A-Read discrimination is performed at time tA; and the C-Read discrimination is performed at time tC. In such a case, only one result of the A-Read discrimination is acquired for each of the cells; and results are not selected based on the result of the C-Read discrimination. Therefore, in the case where the value of the object cell is “E” and the value of the adjacent cell is “C,” the shift amount of the threshold distribution becomes large; and there is a high possibility of a portion of the cells for which the original value is “E” being determined to be value “A.” Accordingly, in the comparative example, the precision of the reading is low.

A second comparative example will now be described.

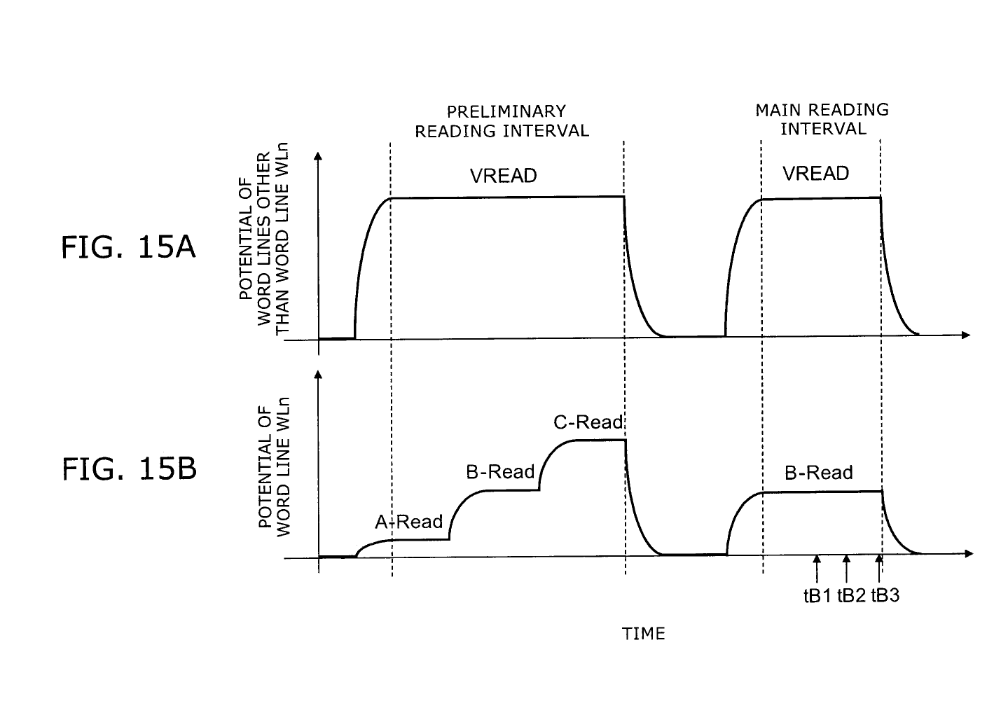

FIGS. 15A and 15B are timing charts showing the operation of the L page read of the comparative example, where the horizontal axis is the time, and the vertical axis is the potentials.

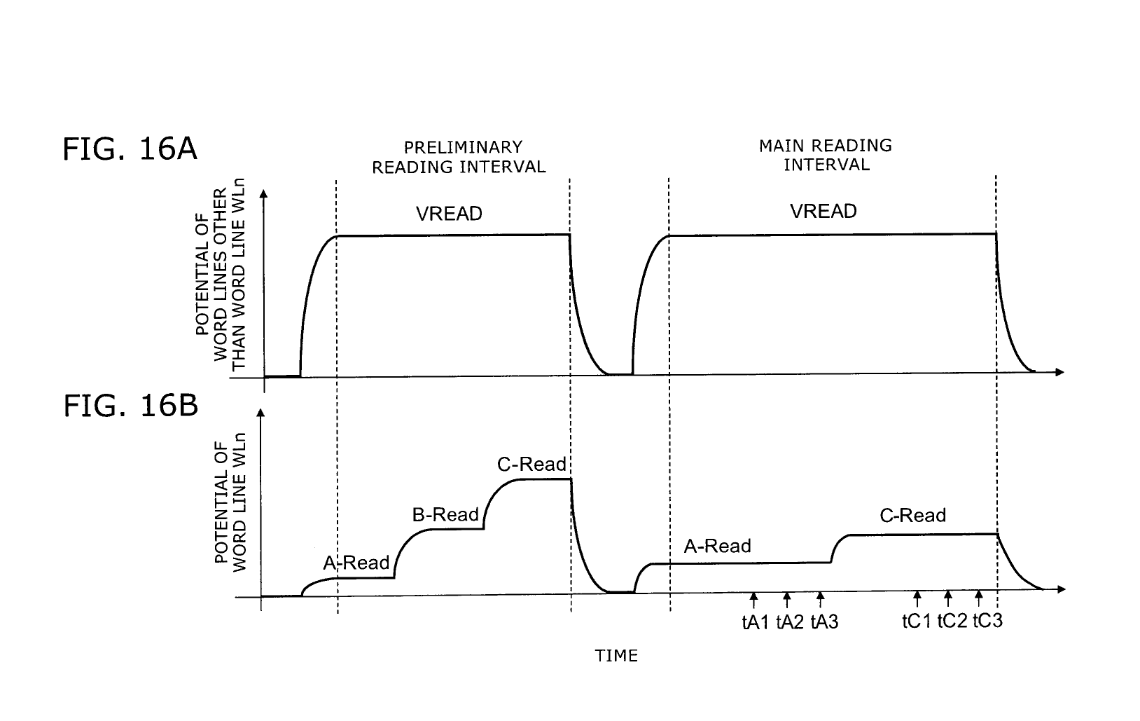

FIGS. 16A and 16B are timing charts showing the operation of a U page read of the comparative example, where the horizontal axis is the time, and the vertical axis is the potentials.

In the comparative example as shown in FIGS. 15A and 15B and FIGS. 16A and 16B, a preliminary reading interval and a main reading interval are provided in the L page read; and a preliminary reading interval and a main reading interval are provided in the U page read. In each of the preliminary reading intervals, the potentials A-Read, B-Read, and C-Read are sequentially applied to the word line WLn; and the value of the cell is temporarily determined.

In the main reading interval of the L page read, the potential B-Read is applied to the word line WLn; and the B-Read discrimination is performed at each of times tB1, tB2, and tB3. Then, as a result of the determination of the preliminary reading interval, the result discriminated at time tB1 is acquired in the case where both of the values of the adjacent cells disposed on the two sides of the object cell are “E” or “B;” the result discriminated at time tB2 is acquired in the case where one of the values of the adjacent cells disposed on the two sides of the object cell is “E” or “B” and the other is “A” or “C;” and the result discriminated at time tB3 is acquired in the case where both of the values of the adjacent cells disposed on the two sides of the object cell are “A” or “C.”

Similarly, in the main reading interval of the U page read, the potential A-Read is applied to the word line WLn; the A-Read discrimination is performed at each of times tA1, tA2, and tA3; and one selected from the discrimination results is acquired based on the values of the adjacent cells obtained in the preliminary reading interval. Then, the potential C-Read is applied to the word line WLn; the C-Read discrimination is performed at each of times tC1, tC2, and tC3; and one selected from the discrimination results is acquired based on the values of the adjacent cells obtained in the preliminary reading interval.

According to the comparative example, by providing the preliminary reading interval prior to the main reading interval, the data can be read by correcting the reading conditions of the main reading interval based on the values of the adjacent cells that are temporarily determined in the preliminary reading interval. However, because the discrimination of the value of the cell is performed twice in the comparative example, the time necessary for the read-out operation undesirably becomes exceedingly long. Accordingly, in the comparative example, the speed of the read-out operation is low.

In the case where the reading conditions are corrected based on only the values of the adjacent cells as in the comparative example, there are cases where the precision of the read-out operation undesirably decreases. For example, as shown in FIG. 8, the adjacent cell coupling to which the object cell is subjected is small in the case where the value of the object cell is “C” and both of the values of the adjacent cells are “C.” However, in the case where the state of the cell is discriminated at time tC3 in such a case, the reading conditions are corrected excessively; and the precision undesirably decreases.

Conversely, according to the first embodiment described above, there is little increase of the read-out time because the result of the A-Read discrimination is selected by utilizing the result of the C-Read discrimination in the original read-out operation without providing the preliminary reading interval. Accordingly, the read-out operation is faster than that of the second comparative example. Compared to the first comparative example, the time necessary for the read-out operation of the first embodiment is increased by only the time T1 necessary for the operation of the sense amplifier SA and the time T2 to acquire the result of the A-Read discrimination from one selected from the data latches DL1 to DL3 based on the result of the C-Read discrimination.

In the first embodiment, because the reading conditions are corrected only in the case where the effect of the adjacent cell coupling on the read-out operation is particularly large, the precision of the read-out operation can be increased effectively without greatly increasing the time necessary for the read-out operation. Further, the reading conditions are not corrected excessively in the case where the adjacent cell coupling is small. Accordingly, the precision of the reading is high.

A second embodiment will now be described.

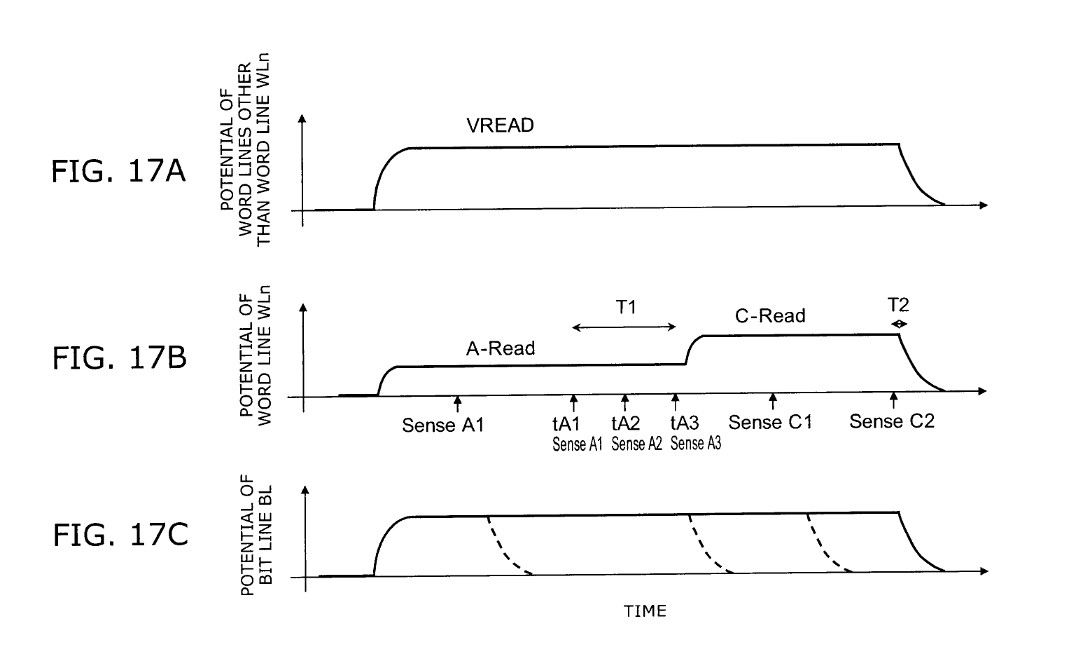

FIGS. 17A to 17C are timing charts showing the operation of the U page read of the embodiment, where the horizontal axis is the time, and the vertical axis is the potentials.

In the U page read of the embodiment as shown in FIGS. 17A to 17C, the C-Read discrimination is performed twice after performing the A-Read discrimination twice.

In the first A-Read discrimination, the reading potential A-Read is set to be low; and a discrimination of low precision is performed. In such a case, among the cells for which the values are “E,” only the cells for which the thresholds are relatively low are switched to the ON state; and the other cells are switched to the OFF state. Therefore, for the cells that are switched to the ON state, the value can be reliably determined to be “E.” For the cells for which the value is determined to be “E,” the potential of the bit line BL is reduced to the ground potential GND.

Then, in the second A-Read discrimination, the discriminations at times tA1, tA2, and tA3 described above are performed; and the results are stored respectively in the data latches DL1 to DL3. In such a case, the potential of the bit line BL is reduced to the ground potential GND for the cells for which the value is determined to be “E” for any of the discrimination results at times tA1, tA2, and tA3.

In the first C-Read discrimination, the reading potential C-Read is set to be high; and a discrimination of low precision is performed. In such a case, among the cells for which the value is “C,” only the cells for which the threshold is relatively high are switched to the OFF state; and the other cells are switched to the ON state. Therefore, the value can be reliably determined to be “C” for the cells that are switched to the OFF state. For the cells for which the value is determined to be “C,” the potential of the bit line BL is reduced to the ground potential GND. Then, the second C-Read discrimination is performed; and one of the results of the A-Read discrimination at times tA1, tA2, and tA3 described above is employed using the results.

According to the embodiment, the current consumption as an entirety can be reduced because the potential of the bit line is reduced to the ground potential for the cells for which the value is established for each discrimination. Otherwise, the configuration, the operations, and the effects of the embodiment are similar to those of the first embodiment described above.

A third embodiment will now be described.

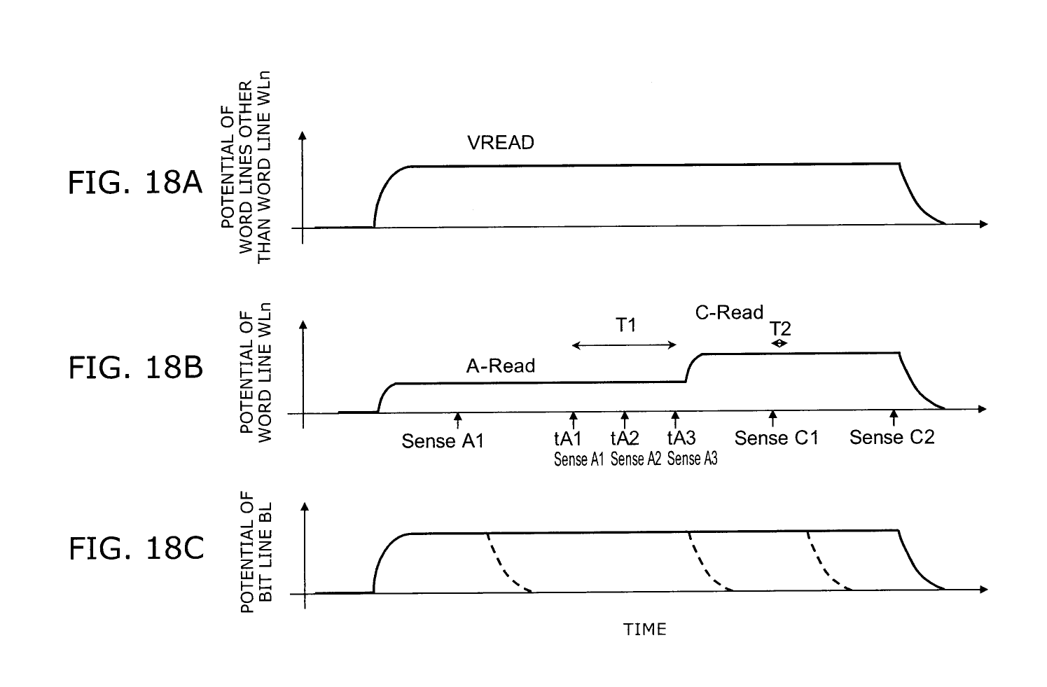

FIGS. 18A to 18C are timing charts showing the operation of the U page read of the embodiment, where the horizontal axis is the time, and the vertical axis is the potentials.

In the embodiment as shown in FIGS. 18A to 18C, similarly to the second embodiment described above, the C-Read discrimination is performed twice after performing the A-Read discrimination twice in the U page read. However, in the embodiment, the result of the A-Read discrimination is selected based on the result of the first C-Read discrimination.

According to the embodiment, the selection of the result of the A-Read discrimination based on the result of the first C-Read discrimination can be implemented in parallel with the second C-Read discrimination. Therefore, compared to the second embodiment described above, the time necessary for the U page read is shorter by the time T2. Thereby, an even faster read-out operation can be realized. On the other hand, the precision of the reading is higher in the second embodiment described above because the result of the A-Read discrimination is selected after the values of all of the cells are established and by using the results of the establishing. Otherwise, the configuration, the operations, and the effects of the embodiment are similar to those of the second embodiment described above.

A fourth embodiment will now be described.

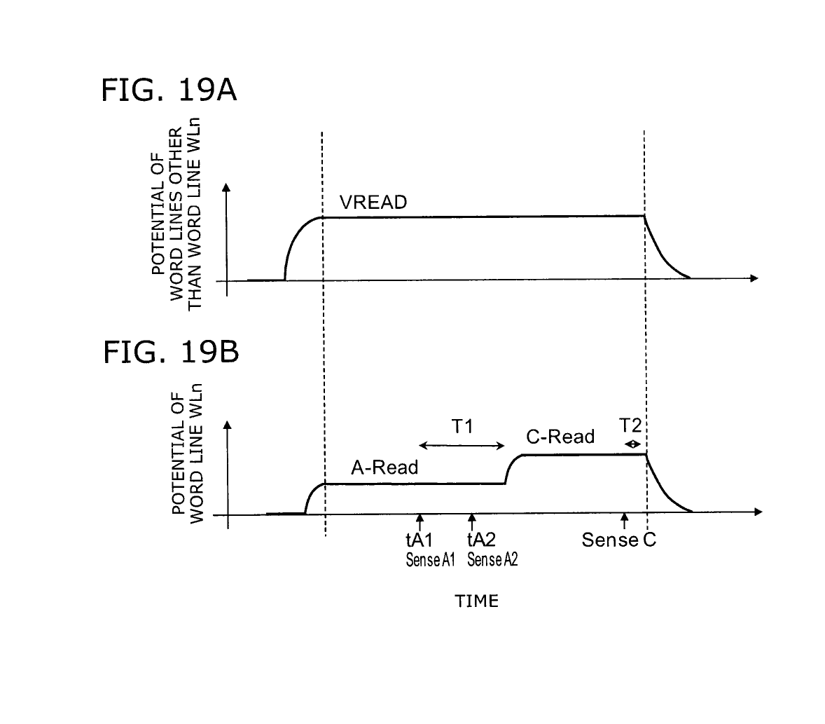

FIGS. 19A and 19B are timing charts showing the operation of the U page read of the embodiment, where the horizontal axis is the time, and the vertical axis is the potentials.

In the A-Read discrimination of the embodiment as shown in FIGS. 19A and 19B, the potential of the node SEN is sensed at the two timings of times tA1 and tA2; the sensing result of time tA1 is stored in the data latch DL1; and the sensing result of time tA2 is stored in the data latch DL2. Then, the C-Read discrimination is performed; latch value “1” is stored in the data latch DL3 if the value of the cell is “C;” and latch value “0” is stored in the data latch DL3 if the value of the cell is a value other than “C.” Thus, in the embodiment, the potential of the node SEN is measured twice in the A-Read discrimination.

Then, the result stored in the data latch DL1 is employed as the result of the A-Read discrimination in the case where the OR of the latched values of the pair of adjacent cells disposed on the two sides of the object cell is “0,” that is, in the case where both of the values of the adjacent cells are values other than “C” and both of the latched values are “0.” On the other hand, the result stored in the data latch DL2 is employed as the result of the A-Read discrimination in the case where the OR recited above is “1,” that is, in the case where one or both of the values of the adjacent cells is “C” and at least one of the latched values is “1.” That is, the result sensed at time tA1 is employed in the case of “two sides: other than C”; and the result sensed at time tA2 is employed in the case of “one side: C” and in the case of “two sides: C”.

Compared to the first embodiment described above, the time T1 can be shortened in the embodiment because the sensing of the potential of the node SEN is performed only twice at times tA1 and tA2 in the A-Read discrimination. Thereby, an even faster read-out operation can be realized. Compared to the first embodiment described above, the number of the data latches DL provided in each of the sense amplifiers SA can be reduced by one. On the other hand, according to the first embodiment described above, because the combinations of the values of the adjacent cells are divided into three cases, the adjacent cell coupling can be considered more precisely; and the precision of the reading can be increased even more. Otherwise, the configuration, the operations, and the effects of the embodiment are similar to those of the first embodiment described above.

A fifth embodiment will now be described. The embodiment differs from the fourth embodiment described above in that the result of the A-Read discrimination is selected using the AND of the latched values of the pair of adjacent cells instead of the OR. In the embodiment, the result sensed at time tA1 is acquired in the case where the AND of the latched values is “0,” that is, in the case where at least one of the latched values is “0” in the case of “two sides: other than C” or in the case of “one side: C”. On the other hand, the result sensed at time tA2 is acquired in the case where the AND of the latched values is “1,” that is, in the case where both of the latched values are “1” in the case of “two sides: C”. Otherwise, the configuration, the operations, and the effects of the embodiment are similar to those of the fourth embodiment described above.

A sixth embodiment will now be described.

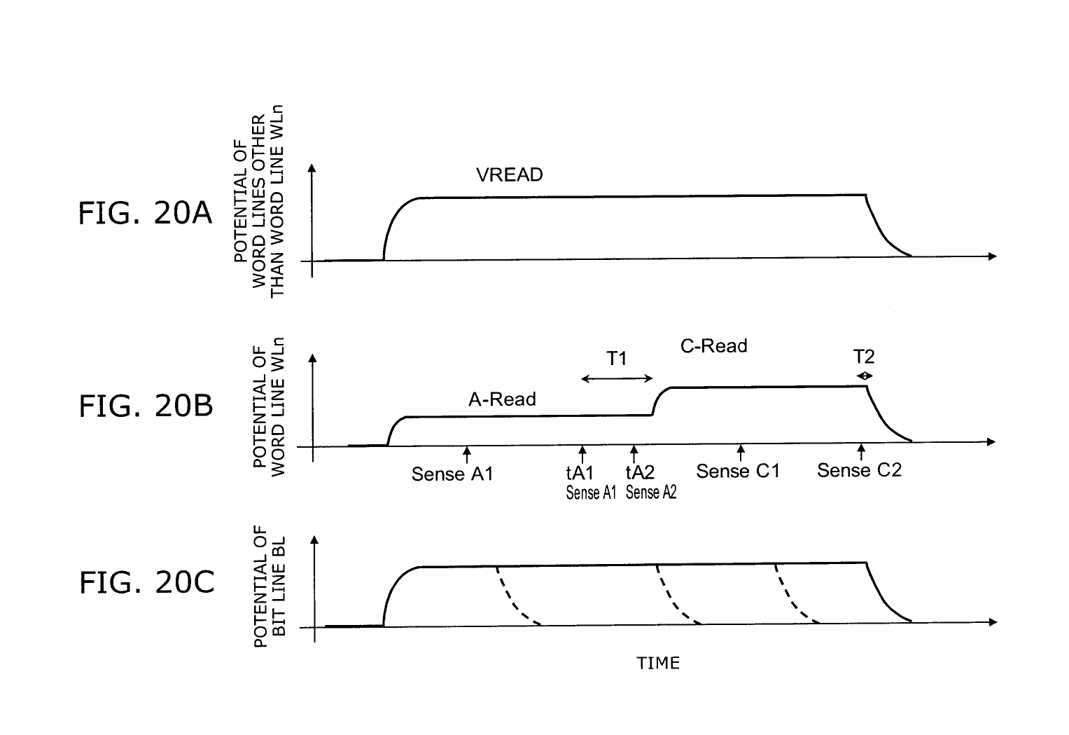

FIGS. 20A to 20C are timing charts showing the operation of the U page read of the embodiment, where the horizontal axis is the time, and the vertical axis is the potentials.

As shown in FIGS. 20A to 20C, the embodiment is an example of a combination of the second embodiment and the fourth embodiment described above. Namely, in the embodiment, the C-Read discrimination is performed twice after performing the A-Read discrimination twice in the U page read. Then, the potential of the node SEN is measured at the two timings of times tA1 and tA2 in the second A-Read discrimination; and the result of the A-Read discrimination is selected based on the result of the second C-Read discrimination. Otherwise, the configuration, the operations, and the effects of the embodiment are similar to those of the second and fourth embodiments described above. Similarly to the embodiment, the second embodiment described above may be combined with the fifth embodiment; and the third embodiment may be combined with the fourth or fifth embodiment.

Although an example is illustrated in each of the embodiments described above in which reading conditions having multiple levels corresponding to the degree of the adjacent cell coupling are realized by measuring the potential of the node SEN at different timings, the invention is not limited thereto; and the reading conditions having the multiple levels may be realized by causing other factors to be different. For example, the reading potential of the word line WLn of the page to be read may be different. For example, in the A-Read discrimination in such a case, the data of the cell, in the state in which a reading potential A-Read1 is applied to the word line WLn, is read and stored in the data latch DL1; then, the data, in the state in which a reading potential A-Read2 that is higher than the reading potential A-Read1 is applied to the word line WLn, is read and stored in the data latch DL2; and then, the data, in the state in which a reading potential A-Read3 that is higher than the reading potential A-Read2 is applied to the word line WLn, is read and stored in the data latch DL3. Then, the C-Read discrimination is performed; the value stored in the data latch DL1 is employed in the case of “two sides: other than C”; the value stored in the data latch DL2 is employed in the case of “one side: C”; and the value stored in the data latch DL3 is employed in the case of “two sides: C”. Or, the potential of the word line WLn may be different due to a coupling effect by causing the pass potential VREAD of the word line WL (n+1) which is adjacent to the word line WLn to be different.

According to the embodiments described above, a semiconductor memory device having a fast read-out operation and high precision of the reading can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a plurality of memory cell;
a plurality of sense amplifiers;
a plurality of bit lines configured to connect the sense amplifiers to the memory cell;
a word line commonly connected to the memory cell; and
a control circuit being configured to perform a first read operation and a second read operation,
the control circuit being configured to perform the plurality of first sense operations when applying a first reading voltage to the word line in the first read operation,
the control circuit being configured to perform a second sense operation when applying a second reading voltage to the word line in the second read operation, the control circuit being configured to select one of informations read out by the plurality of sense operations based on data stored in adjacent memory cells.

2. The device according to claim 1, further comprising:
a plurality of data latches including first and second data latches, wherein
the second reading voltage is higher than the first reading voltage,
the plurality of first sense operations including a first operation and a second operation,
the control circuit being configured to perform the first operation and the second operation in order when applying a first reading voltage to the word line in the first read operation, the informations including a first information and a second information, the first information being a result of the first operation, the second information being a result of the second operation,
the control circuit being configured to store the first information in the first data latch and store the second information in the second data latch,
the control circuit being configured to select the first information when the adjacent memory cells hold values other than the highest value, and
the control circuit being configured to select the second information when the adjacent memory cells hold the highest value.

3. The device according to claim 2, wherein
the plurality of data latches further includes a third data latch,
the control circuit is configured, when applying the first reading voltage to the word line, to discriminate the value of the one of the memory cells using a third operation and store the result of the discrimination in the third data latch, the third operation is configured to enable the discrimination of whether or not the value of the one of the memory cells is the lowest value when the value of one of the two memory cells is the highest value and the value of the other of the two memory cells is not the highest value, and
the control circuit employs the result stored in the third data latch as the discrimination result of whether or not the value of the one of the memory cells is the lowest value when the value of one of the two memory cells is the highest value and the value of the other of the two memory cells is not the highest value.

4. The device according to claim 2, wherein the control circuit employs the result stored in the first data latch as the discrimination result of whether or not the value of the one of the memory cells is the lowest value when the value of one of the two memory cells is the highest value and the value of the other of the two memory cells is not the highest value.

5. The device according to claim 2, wherein the control circuit employs the result stored in the second data latch as the discrimination result of whether or not the value of the one of the memory cells is the lowest value when the value of one of the two memory cells is the highest value and the value of the other of the two memory cells is not the highest value.

6. The device according to claim 1, wherein
each of the sense amplifiers further includes a capacitor,
a potential of a positive side of the capacitor is measured after a first time has elapsed from when a charge stored in the capacitor is caused to start to flow in the memory cell transistor in the first condition, and
the potential of the positive side of the capacitor is measured after a second time has elapsed from when the charge stored in the capacitor is caused to start to flow in the memory cell transistor in the second condition, the second time being longer than the first time.

7. A semiconductor memory device, comprising:
a plurality of memory cells;
a plurality of sense amplifiers;
a plurality of bit lines configured to connect the sense amplifiers to the memory cells;
a word line commonly connected to the memory cells; and
a control circuit,
each of the sense amplifiers including:
first to third data latches; and
a capacitor,
the control circuit, while applying a first reading voltage to the word line, being configured to discriminate a value of the memory cell by measuring a potential of a positive side of the capacitor after a first time has elapsed from when a charge stored in the capacitor is caused to start to flow in the memory cell and store the result of the discrimination in the first data latch,
the control circuit, while applying the first reading voltage to the word line, being configured to discriminate the value of the memory cell by measuring the potential of the positive side of the capacitor after a second time has elapsed from when the charge stored in the capacitor is caused to start to flow in the memory cell and store the result of the discrimination in the second data latch, the second time being longer than the first time,
the control circuit, while applying the first reading voltage to the word line, being configured to discriminate the value of the memory cell by measuring the potential of the positive side of the capacitor after a third time has elapsed from when the charge stored in the capacitor is caused to start to flow in the memory cell and store the result of the discrimination in the third data latch, the third time being longer than the second time,
the control circuit being configured to discriminate whether or not the values of the memory cells of the word line are the highest value while applying a second reading voltage to the word line, the second reading voltage being higher than the first reading voltage,
the control circuit being configured to employ the result stored in the first data latch as the discrimination result of whether or not the value of one of the memory cells is the lowest value when both of values of two of the memory cells disposed on two sides adjacent to the one of the memory cells are values other than the highest value, employ the result stored in the second data latch as the discrimination result of whether or not the value of the one of the memory cells is the lowest value when the value of one of the two memory cells is the highest value and the value of the other of the two memory cells is not the highest value, and employ the result stored in the third data latch as the discrimination result of whether or not the value of the one of the memory cells is the lowest value when both of the values of the two memory cells are the highest value.

8. A semiconductor memory device, comprising:
a semiconductor substrate including a plurality of active areas to extend in a first direction;
a plurality of word lines provided on the semiconductor substrate to extend in a second direction;
a plurality of bit lines connected respectively to the active areas;
a source line connected to the plurality of active areas;
charge storage layers disposed between each of the active areas and each of the word lines;
sense amplifiers connected to the bit lines; and
a control circuit,
each of the sense amplifiers including a plurality of data latches,
memory cell transistors being formed at intersections between each of the active areas and each of the word lines, the memory cell transistors being configured to be programmed with data having values of multiple levels,
the control circuit being configured to use a plurality of reading conditions to discriminate the data stored in a plurality of the memory cell transistors of one of the word lines while applying a first reading potential to the one of the word lines and respectively store the results discriminated using the reading conditions in the data latches,
the control circuit being configured to discriminate, while applying a second reading potential to the one of the word lines, the data stored in the memory cell transistors of the one of the word lines,
the control circuit being configured to employ one selected from the results stored in the plurality of data latches for one of the memory cell transistors based on the discrimination result when the second reading potential is applied to the memory cell transistor disposed adjacently to the one of the memory cell transistors.

9. The device according to claim 8, wherein
the plurality of data latches includes first and second data latches,
the second reading potential is higher than the first reading potential,
the plurality of reading conditions includes a first condition and a second condition, the first condition being configured to enable the discrimination of whether or not a value of the one of the memory cell transistors is a value of the lowest threshold when both of values of two of the memory cell transistors of the plurality of memory cell transistors of the word line are values other than a value having the highest threshold, the second condition being configured to enable the discrimination of whether or not the value of the one of the memory cell transistors is the lowest value when both of the values of the two of the memory cell transistors are the highest value, the two of the memory cell transistors being disposed on two sides adjacent to the one of the memory cell transistors,
the control circuit being configured to store the discrimination result of the first condition in the first data latch and store the discrimination result of the second condition in the second data latch, and
the control circuit, when the second reading potential is applied, being configured to employ the result stored in the first data latch as the discrimination result of whether or not the value of the one of the memory cell transistors is the lowest value when both of the values of the two memory cell transistors are values other than the highest value and employ the result stored in the second data latch as the discrimination result of whether or not the value of the one of the memory cell transistors is the lowest value when both of the values of the two memory cell transistors are the highest value.

10. The device according to claim 9, wherein
the plurality of data latches further includes a third data latch,
the control circuit is configured, when applying the first reading potential to the word line, to discriminate the value of the one of the memory cell transistors using a third condition and store the result of the discrimination in the third data latch, the third condition is configured to enable the discrimination of whether or not the value of the one of the memory cell transistors is the lowest value when the value of one of the two memory cell transistors is the highest value and the value of the other of the two memory cell transistors is not the highest value, and
the control circuit employs the result stored in the third data latch as the discrimination result of whether or not the value of the one of the memory cell transistors is the lowest value when the value of one of the two memory cell transistors is the highest value and the value of the other of the two memory cell transistors is not the highest value.

11. The device according to claim 9, wherein the control circuit employs the result stored in the first data latch as the discrimination result of whether or not the value of the one of the memory cell transistors is the lowest value when the value of one of the two memory cell transistors is the highest value and the value of the other of the two memory cell transistors is not the highest value.

12. The device according to claim 9, wherein the control circuit employs the result stored in the second data latch as the discrimination result of whether or not the value of the one of the memory cell transistors is the lowest value when the value of one of the two memory cell transistors is the highest value and the value of the other of the two memory cell transistors is not the highest value.

13. The device according to claim 8, wherein
each of the sense amplifiers further includes a capacitor,
a potential of a positive side of the capacitor is measured after a first time has elapsed from when a charge stored in the capacitor is caused to start to flow in the memory cell transistor in the first condition, and
the potential of the positive side of the capacitor is measured after a second time has elapsed from when the charge stored in the capacitor is caused to start to flow in the memory cell transistor in the second condition, the second time being longer than the first time.

14. An operation method for a semiconductor memory device, comprising:
performing a first read operation to perform a plurality of first sense operations for a plurality of memory cells while applying a first reading voltage to a word line connected to the memory cells;
performing a second read operation to perform a second sense operation for the plurality of memory cells while applying a second reading voltage to the word line; and
selecting one of data read out by the plurality of the first sense operations for one of the memory cells based on data stored in adjacent memory cells of the one of the memory cells read out by the second sense operation.
